(19) United States
(12) Patent Application Publication
(10) Pub. No.: US 2014/0137933 A1
(43) Pub. Date: May 22, 2014

(54) DEVICES AND METHODS FOR PROVIDING CARRIER SELECTIVE CONTACT DEVICES

(71) Applicants: Kunal Ghosh, Tempe, AZ (US); Stuart Bowden, Tempe, AZ (US); Christiana Honsberg, Tempe, AZ (US)

(72) Inventors: Kunal Ghosh, Tempe, AZ (US); Stuart Bowden, Tempe, AZ (US); Christiana Honsberg, Tempe, AZ (US)

(73) Assignee: Arizona Board of Regents, a body corporate of the State of Arizona, acting for and on behalf of Ariz, Scottsdale, AZ (US)

(21) Appl. No.: 14/086,364

(22) Filed: Nov. 21, 2013

Related U.S. Application Data
(60) Provisional application No. 61/729,257, filed on Nov. 21, 2012.

(51) Int. Cl. H01L 31/0248; H01L 31/20

(52) U.S. Cl. CPC H01L 31/0248; H01L 31/20
USPC 136/256; 438/94

(57) ABSTRACT

Devices comprising: an absorbing medium (AM) having first and second sides; a first membrane layer (ML) having first and second sides, wherein the first side of the first ML contacts the first side of the AM; a second ML having first and second sides, wherein the first side of the second ML contacts the second side of the AM; a first contact in contact with the second side of the first ML; and a second contact in contact with the second side of the second ML, wherein a first band alignment mismatch between the first contact and the AM causes a first surface of the AM on the first side of the AM to be in inversion, and wherein a second band alignment mismatch between the second contact and the AM causes a second surface of the AM on the second side of the AM to be under accumulation.

### CROSS REFERENCE TO RELATED APPLICATION

This application claims the benefit of U.S. Provisional Patent Application No. 61/729,257, filed Nov. 21, 2012, which is hereby incorporated by reference herein in its entirety.

### STATEMENT REGARDING FEDERALLY SPONSORED RESEARCH OR DEVELOPMENT

The invention was made with government support under Grant No. 1041895 awarded by the National Science Foundation. The government has certain rights in the invention.

### TECHNICAL FIELD

The disclosed subject matter relates to devices and methods for providing carrier selective contact devices.

### BACKGROUND

Photovoltaic technologies from their inception have primarily relied on p-n junction technology for device fabrication. As a consequence, efficiency limit calculations, such as detailed balance, for photovoltaic technologies are typically based on the presence of a p-n junction.

The principle of detailed balance states that, under steady state conditions, the inverse process of each microscopic process balances the microscopic process. The thermodynamic limit of efficiency of solar cells, commonly termed the Shockley-Queisser limit (SQ limit), is governed by the principle of detailed balance. In determining the SQ limit, a few assumptions are typically made about the photovoltaic device operating at that SQ limit. Two assumptions of particular interest in this context are: (1) that there is a perfect collection of carriers after absorption of photons; and (2) that intrinsic recombination is the only allowed recombination mechanism.

A perfect collection of carriers means that every electron-hole pair generated spontaneously separates and collects at their respective contacts in the device. However, in a practicable device, this is not feasible without an electric field separating the electrons and the holes. In typical experimental devices, a p-n junction is used to create the electric field separating the electrons and the holes. But, the formation of a p-n junction comes at a cost to the overall device performance.

For example, the built-in voltage (V_{bi}) of a solar cell device with a p-n junction dictates the maximum achievable open circuit voltage (V_{oc}) of the device. However, a higher V_{bi} in a device typically requires a higher doping on one side or on both sides of the device's p-n junction, a higher doping introduces more defects in the device's materials thereby enhancing Shockley-Read-Hall recombination (SRH recombination), and such enhanced SRH recombination causes total recombination in the devices to be determined by extrinsic defect-assisted SRH recombination rather than intrinsic recombination mechanisms (such as radiative recombination and auger recombination). The total recombination being determined by extrinsic defect-assisted SRH recombination puts a limit on the maximum achievable V_{oc} and, hence, the overall efficiency of a p-n junction solar cell is lower than the SQ limit.

Accordingly, new technologies for providing carrier selective contact devices are desired.

### SUMMARY

Devices and methods for providing carrier selective contact devices are provided. In accordance with some embodiments, devices for providing carrier selective contact devices are provided, the devices comprising: an absorbing medium for absorbing light having a first side and a second side; a first membrane layer having a first side and a second side, wherein the first side of the first membrane layer is in contact with the first side of the absorbing medium; a second membrane layer having a first side and a second side, wherein the first side of the second membrane layer is in contact with the second side of the absorbing medium; a first contact in contact with the second side of the first membrane layer; and a second contact in contact with the second side of the second membrane layer, wherein a first band alignment mismatch between the first contact and the absorbing medium causes a first surface of the absorbing medium on the first side of the absorbing medium to be in inversion, and wherein a second band alignment mismatch between the second contact and the absorbing medium causes a second surface of the absorbing medium on the second side of the absorbing medium to be under accumulation.

In accordance with some embodiments, methods for providing a carrier selective contact device are provided, the methods comprising: providing an absorbing medium for absorbing light having a first side and a second side; providing a first membrane layer having a first side and a second side, wherein the first side of the first membrane layer is in contact with the first side of the absorbing medium; providing a second membrane layer having a first side and a second side, wherein the first side of the second membrane layer is in contact with the second side of the absorbing medium; providing a first contact in contact with the second side of the first membrane layer; and providing a second contact in contact with the second side of the second membrane layer, wherein a first band alignment mismatch between the first contact and the absorbing medium causes a first surface of the absorbing medium on the first side of the absorbing medium to be in inversion, and wherein a second band alignment mismatch between the second contact and the absorbing medium causes a second surface of the absorbing medium on the second side of the absorbing medium to be under accumulation.

### BRIEF DESCRIPTION OF THE DRAWINGS

FIG. 1 shows an example of a carrier selective contact device in accordance with some embodiments.

FIG. 2 shows an example of a schematic diagram of a selective carrier contact device in accordance with some embodiments.

FIG. 3 shows a band diagram of Gallium Phosphide on silicon in accordance with some embodiments.

FIG. 4 shows an example of a structure for a carrier selective contact device in accordance with some embodiments.

FIG. 5 shows a diagram of V_{oc} values plotted as a function of device thickness in accordance with some embodiments.

FIG. 6 shows an example of a superlattice in accordance with some embodiments.

### DETAILED DESCRIPTION

In accordance with some embodiments, devices and methods for providing carrier selective contact devices are provided. In some embodiments, these devices and methods can be used to implement solar cell devices which allow selective extraction of carriers by utilizing inversion and accumulation on surfaces of an absorbing medium of the devices. In some embodiments, such solar cell devices can be free of p-n junctions.

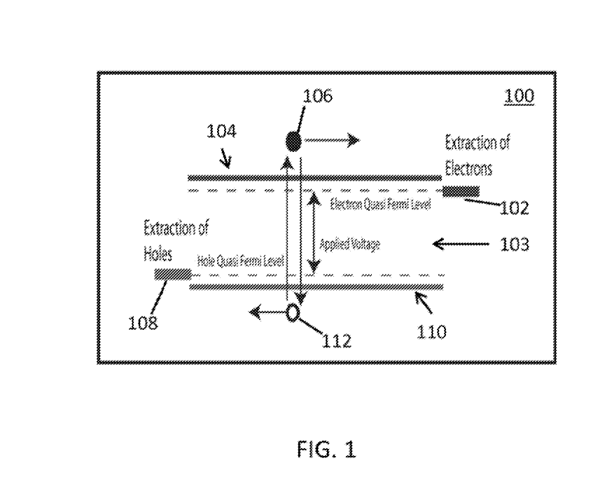

As illustrated by way of example 100 of FIG. 1, in such devices and methods, in some embodiments, efficiency limit calculations, such as detailed balance, can be based on the presence of a contact 102, which is located on one side 104 of an absorbing medium 103 and which extracts electrons 106, and a contact 108, which is located on the other side 110 of absorbing medium 103 and which extracts holes 112.

In some embodiments, a carrier selective contact device can be configured such that the band alignment mismatch between the absorbing medium and the layer through which the currents are extracted is properly split between the conduction band and the valence band. For example, for the layer through which hole extraction takes place, the device can be configured such that a larger fraction of the band offset is in the conduction band. As another example, for the layer through which electron extraction takes place, the device can be configured such that a larger fraction of the band offset is in the valence band.

In some embodiments, a carrier selective contact device can be implemented as a solar cell device. For example, the solar cell device can have a higher efficiency than a p-n junction solar cell due to a closer match to thermodynamic efficiencies than can be achieved with a p-n junction solar cell. Moreover, in some embodiments, a carrier selective contact device implemented as a solar cell device can avoid several key trade-offs and non-idealities of a p-n junction, such as the lifetime degradation in doped materials, the high surface recombination at typical interfaces, and the interactions between the processing steps and the material in the high temperatures required by diffusions or growth.

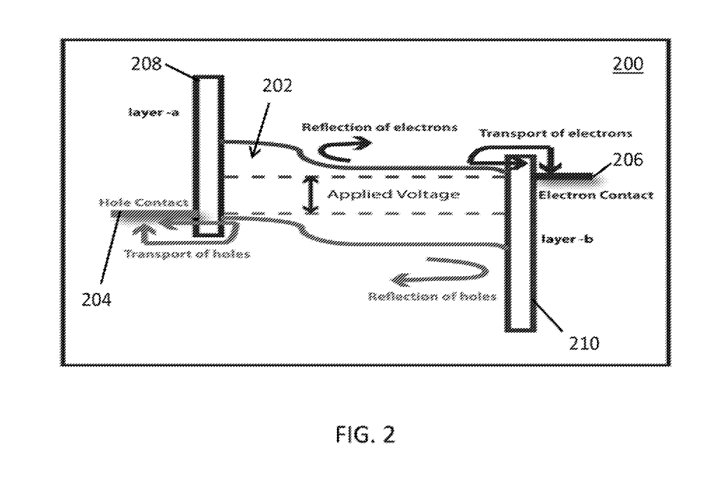

Turning to FIG. 2, FIG. 2 shows an example 200 of a schematic diagram of a selective carrier contact device in accordance with some embodiments. As illustrated, in some embodiments, the device can include an absorbing medium 202, a hole contact 204, an electron contact 206, a layer-a membrane layer 208, and a layer-b membrane layer 210.

In accordance with some embodiments, absorbing medium 202 can be a layer of device 200 in which primary photo-generation occurs. Absorbing medium 202 can be implemented using direct band-gap crystalline semiconductors (e.g., GaAs), indirect band-gap crystalline semiconductors (e.g., Silicon), thin film materials (e.g., CIGS, CdTe) materials, and/or any other suitable substance, material, etc.

In some embodiments, the thickness of the absorbing medium can be chosen so that its absorption of photons can be optimized in accordance with any suitable standard. For example, in some embodiments, for silicon, the thickness can be around 50-80 um. As another example, in some embodiments, for GaAs, the thickness can be around a few hundred nanometers.

In some embodiments, the absorbing medium can be n-doped, p-doped, or intrinsic (i.e., un-doped).

Using an intrinsic material, in accordance with some embodiments, can reduce the amount of defect-induced recombination, thus allowing device 200 to operate near the thermodynamic limit of open-circuit voltage. This is the case because, while an intrinsic material, through an increased series resistance, can detrimentally affect the fill factor of the device, the device operates close to the limiting performance of a photovoltaic device because it does not include a p-n junction, and thus the photo-generated carrier concentration is much higher than the background doping. Thus, in accordance with some embodiments, photo-generated carriers, rather than background doping, determine the conductivity of the device at operating conditions and hence the selection of intrinsic material for the absorbing medium does not affect the fill factor.

In accordance with some embodiments, membrane layers 208 and 210 can be used to physically separate highly defective layers of contact 204 and 206 from absorbing medium 202, while also electrically transferring charge carriers generated in the absorbing medium to the contacts.

In some embodiments, the membrane layers can be intrinsic (i.e., un-doped).

In some embodiments, the membrane layers can be high quality epitaxial, can be amorphous or polycrystalline materials, and/or can be any other suitable material(s).

In some embodiments, the membrane layers can be selected to have a certain band gap and a certain band alignment with the absorbing medium. For example, in some embodiments, the membrane layers can be selected to have a band gap that is large enough so that the carrier concentration in the layers is negligible. In some embodiments, the bands of the layers can be aligned with that of the absorbing medium such that they provide negligible impediment to the flow of a particular carrier type (e.g., holes for layer-a 208 and electrons for layer-b 210, in FIG. 2) and block the flow of carrier of opposite polarity (e.g., electrons for layer-a 208 and holes for layer-b 210, in FIG. 2). However, this does not mean that the corresponding band offsets have to be negligible in all embodiments, as the barrier to the carrier flow can be the net difference between band offset and band bending at the surface of the absorber medium in some embodiments.

In some embodiments, contacts 204 and 206 can be used to extract currents from the device and control the band bending at the surfaces of the absorbing medium.

In some embodiments, each of contacts 204 and 206 can be implemented using a combination of two layers: (1) an outer layer (away from the absorbing medium surface), which is a metal; and (2) an inner layer, which is a highly doped layer of the same material as the corresponding membrane layer (e.g., layer 208 for contact 204, and layer 210 for contact 206).

In some embodiments, the inner layer can be selected to be the same material as the membrane layer so that there is no band alignment mismatch between the inner layer and the corresponding membrane layer, and thus current can flow through the interface between these layers without any hindrance.

In some embodiments, the outer layer of the contacts can be selected to be any suitable metal, such as silver, aluminum, copper, etc. Aluminum and copper can be used as this outer layer in some embodiments because the surface band bending of the absorber medium is not controlled by the work-function of the metal in some embodiments. Rather, the inner layer of the contacts controls the band bending at the surfaces of the absorbing medium by pinning the respective quasi-fermi levels (e.g., in FIG. 2, the hole and electron quasi Fermi levels for the front and rear surfaces, respectively) throughout the operating region of the device.

In some embodiments, as shown in FIG. 2, the surface of the absorbing medium at its junction with layer-a has surface band bending which bends differently than the surface of the absorbing medium at its junction with layer-b. As illustrated, the surface of the absorbing medium in contact with layer-a is strongly inverted, while the surface of the absorbing medium in contact with layer-b is under accumulation. This surface band bending can ameliorate the effect of band alignment mismatch at the surfaces of the absorbing medium by lowering the effective barrier that the carriers encounter at the heterointerfaces formed at these surfaces. The effective barriers can be approximated by the differences between band offset and the band bending at the surfaces. In some embodiments, the presence of surface band bending can allow a wide choice of material combinations with significant band alignment mismatch. In some embodiments, the surface band bending can also result in improved field effect surface passivation by actively suppressing the concentration of one type of carrier.

In some embodiments, the operation of a carrier selective contact device can be summarized as follows: under illumination, photo-generation primarily occurs in the absorbing medium, and the photo-generated minority carriers diffuse to the edges of the space charge region on either side of the absorbing medium. As shown in FIG. 2, an inversion region on one side of the absorbing medium provides an electric field that selectively extracts one type of carrier (i.e., holes in the example of FIG. 2) while repelling the carrier of opposite polarity (i.e., electrons in the example of FIG. 2). As also shown in FIG. 2, an accumulation region on the other side of the absorbing medium provides an electric field that selectively extracts the other type of carrier (i.e., electrons in the example of FIG. 2) while repelling the carrier of opposite polarity (i.e., holes in the example of FIG. 2).

In accordance with some embodiments, a carrier selective contact device as described herein can be implemented in any suitable manner. For example, in some embodiments, a selective carrier contact device can be implemented by depositing thin films of dielectric material with surface passivation quality on an absorbing medium formed from c-Si and with front and rear contacts. As set forth above, any other suitable material can be used for the absorbing medium in some embodiments.

In some embodiments, Gallium Phosphide (GaP) can be used as a membrane layer 208 through which holes are extracted to contact 204. Theoretical calculations can be used to show that the valence band offset between c-Si and GaP is 0.27 eV and when the effect of atomic relaxation is considered, the value can reach 0.45 eV. In some embodiments, the total band offset (difference between band gap of c-Si and GaP) can be calculated to be 1.14 eV and, hence, a larger fraction of band offset can be found to be in the conduction band, making GaP a suitable material for membrane layer 208 through which hole extraction occurs.

In some embodiments, a-Si or a-SiC can be used as a membrane layer 210 through which electrons are extracted to contact 206.

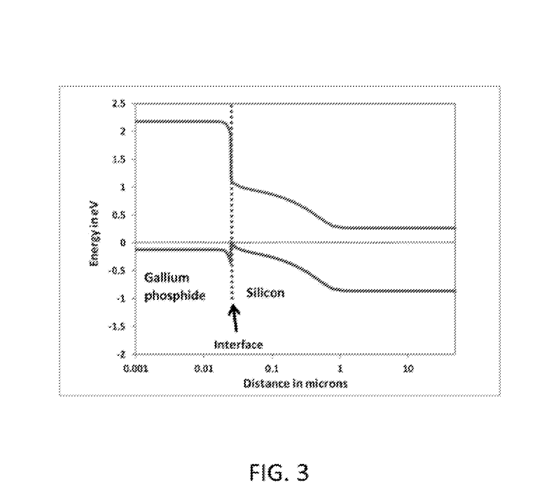

An example of a band diagram of Gallium phosphide (GaP) on silicon is illustrated in FIG. 3 in accordance with some embodiments. The band diagram shows that the surface of c-Si is strongly inverted. In addition, this diagram shows that the barrier that the holes encounter at the heterointerface between GaP and silicon, measured by the difference between valence band offset and the band bending, is small. This results in negligible impediment to the flow of holes, while simultaneously repelling the electrons, as seen from the band alignment in the conduction band.

As another example, in some embodiments, a selective carrier contact device can be implemented by applying organic materials on c-Si. The organic layer can have a dual role of reducing the defect density at the silicon surface while also causing strong band bending under the organic layer, which can invert the surface of silicon on the front and acts as a mirror to the minority carrier on the rear.

To realize such a structure, in some embodiments, the organic layer can provide surface passivation, can be chemically robust, and can offer the possibility of further functionalization such as chemically adhering to an encapsulant or another photovoltaic device.

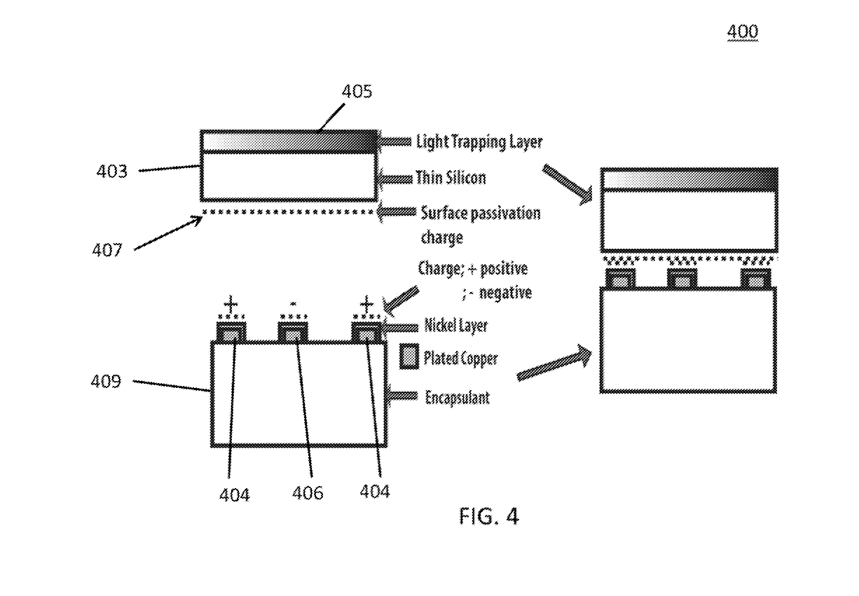

Turning to FIG. 4, an example 400 of a structure for a carrier selective contact device in accordance with some embodiments is shown. As illustrated, carrier selective contact device 400 can be implemented with contacts 404 and 406 formed from metal lines on the rear. In this device, a thin layer of silicon 403 (which can be ultra-thin in some embodiments) can be used as the absorbing medium. A light trapping nanostructured layer 405 can be provided on the front of silicon 403 and a surface passivation layer 407 can be provided on the rear. An encapsulant 409 with charged films that induce the surface band bendings can be bonded to silicon 403.

In accordance with some embodiments, the limiting V_{oc} of a carrier selective contact device implemented as a solar cell device can be calculated under high level injection (HLI). Under HLI, V_{oc} and short-circuit current (taken equal to photo-generated current) J_{sc} can be given by:

$$\begin{matrix}{V}_{oc} = \frac{2 KT}{q} {log}_{e} ( \frac{n}{{n}_{i}} ) & Eqn . 1 \\ {J}_{sc} = \frac{q}{τ} [ {\int }_{0}^{W} n ( x ) \cdot d x ] + qS ( {n}_{f} + {n}_{b} ) + \frac{{n}^{2}}{{n}_{i}^{2}} {J}_{o} + {qC}_{a} {\int }_{0}^{W} {n}^{3} ( x ) \cdot d x & Eqn . 2\end{matrix}$$

where, n is the excess photo-generated carriers, τ is the Shockley-Read-Hall high level injection lifetime, S is the surface recombination velocity (SRV), n_{f} and n_{b} are the front and rear surface carrier concentration, Cₐ is the ambipolar diffusion coefficient, Jₒ is the reverse saturation current density. W is the thickness of the device, q is the electronic charge, K is the Botzmann's constant and T is the absolute temperature.

In some embodiments, the one-dimensional simulator PC1D can be used to calculate the limiting V_{oc} as a function of device thickness at a fixed short-circuit current (42.5 mA/cm²). The value of Cₐ can be 1.66×10⁻³⁰. Both front and rear surfaces of c-Si in contact with layer-a and layer-b, respectively, can be considered to be perfectly passivated (for the sake of calculation) and can have a SRV value of zero or nearly zero (e.g., 1×10⁻⁵ cm/s can be used to avoid numerical instability during calculations).

As described above, in a carrier selective contact device in accordance with some embodiments, at the front interface of n-doped c-Si, the band alignment mismatches of c-Si with the corresponding contact layers causes a strong band bending resulting in an accumulation of holes and a strongly inverted region near the interface. The presence of these layers can be modeled by putting a negative charge on the front surface of c-Si (or by putting a positive charge on the front surface of c-Si for p-doped c-Si). The negative charge causes a positive image charge in the c-Si, resulting in the band bending and an inversion region.

Because the surfaces are considered to be perfectly passivated for the sake of modeling, assigning a charge on the rear surface is unnecessary, but can be done in some embodiments.

The negative charge (Q) applied on the front surface can be used to define the degree of inversion occurring in c-Si and hence the value of Jₒ. By varying Q from −1×10¹²/cm² to −5×10¹²/cm², it can be determined if a change in Jₒ is observed. If not, the surface can be strongly inverted over this entire range of charge and a value of Q=−1×10¹²/cm² can be taken as an adequate charge.

The bulk doping can be varied from 1×10¹²/cm³ to 1×10¹⁵/cm³ to verify whether the change of the value has any effect on the V_{oc}. If it is observed that the variation causes negligible or no change in V_{oc}, the value of 1×10¹⁵/cm³ can be taken for the bulk doping.

The value of τ can be 10 ms or any other suitable value in some embodiments. Simulation results can be used to show that increasing τ by orders of magnitude (defect free bulk silicon) from the value of 10 ms causes V_{oc} to increase by a negligible amount of 2-3 mV.

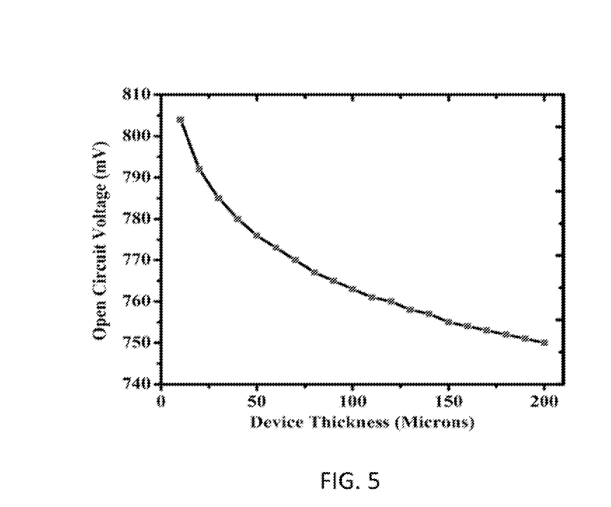

The V_{oc} values plotted as a function of device thickness is shown in FIG. 5. The plots show that V_{oc} increases with decreasing device thickness, with an achievable V_{oc} of greater than 800 mV at 10 um. The carrier selective contact devices thus provide a mechanism to bridge the gap between thermodynamic limits of V_{oc} and that achieved by diffused a p-n junction solar cell.

In some embodiments, material combinations for an electron contact and a hole contact for a given absorbing medium as described herein may not be feasible. In some of such embodiments, a carrier selective contact device can be implemented through a superlattice structure on one side or on both sides of a solar cell.

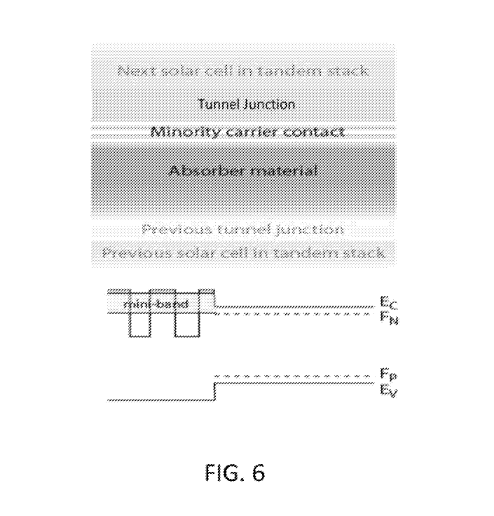

FIG. 6 shows an example of a superlattice in accordance with some embodiments. As illustrated, a quantum well (QW) or superlattice can be implemented such that, on one side of the solar cell, the miniband aligns with the quasi-Fermi level of electrons (as shown in FIG. 6), while, depending on material constraints, on the other side of the device, the mini-band aligns with the hole quasi-Fermi level or has an optimized band alignment matching for hole extraction. In some embodiments, a remaining design constraint can be that, for the carrier not being extracted at a given surface, there is a barrier to that carrier.

An advantage of such a superlattice approach compared to surface inversion is that high conductivity can be achieved with lower absorption in accordance with some embodiments. Other potential advantages, in some embodiments, can relate to incorporation of the superlattice or layers as part of a solar cell structure. For example, in some embodiments, a similar contact can be used to promote tunneling, thus incorporating the emitter, window layer, and tunnel junction into a single structure. Alternately, the use of the superlattice may allow a greater range of materials compared to a surface inversion approach. In practice, because the superlattice approach shown in FIG. 6 is susceptible to presence of interface states, it is likely that, even where a superlattice is used to contact the quasi-Fermi levels, some degree of band bending will also be included.

While the superlattice approach can be readily included in tandem solar cells, if detailed modeling or experiment proves it has particular advantages, it can also be included in low cost solar cells. For example, silicon quantum dots embedded in SiO₂ can be deposited in low-cost, low-temperature approaches.

Although the invention has been described and illustrated in the foregoing illustrative embodiments, it is understood that the present disclosure has been made only by way of example, and that numerous changes in the details of implementation of the invention can be made without departing from the spirit and scope of the invention, which is only limited by the claims which follow. Features of the disclosed embodiments can be combined and rearranged in various ways.

What is claimed is:

1. A device comprising:
an absorbing medium for absorbing light having a first side and a second side;
a first membrane layer having a first side and a second side, wherein the first side of the first membrane layer is in contact with the first side of the absorbing medium;
a second membrane layer having a first side and a second side, wherein the first side of the second membrane layer is in contact with the second side of the absorbing medium;
a first contact in contact with the second side of the first membrane layer; and
a second contact in contact with the second side of the second membrane layer,
wherein a first band alignment mismatch between the first contact and the absorbing medium causes a first surface of the absorbing medium on the first side of the absorbing medium to be in inversion, and
wherein a second band alignment mismatch between the second contact and the absorbing medium causes a second surface of the absorbing medium on the second side of the absorbing medium to be under accumulation.

2. The device of claim 1, wherein the first surface of the absorbing medium has an inversion region that provides an electric field that selectively extracts a first carrier of a particular polarity while repelling a second carrier of the opposite polarity of the first carrier.

3. The device of claim 2, wherein the second surface of the absorbing medium has an accumulation region that provides an electric field that selectively extracts the second carrier while repelling the first carrier.

4. The device of claim 1, wherein the absorbing medium is c-Si.

5. The device of claim 1, wherein the first membrane layer is Gallium Phosphide.

6. The device of claim 1, wherein the second membrane layer is one of a-Si and a-SiC.

7. The device of claim 1, wherein the absorbing medium is 50-80 μm.

8. The device of claim 1, wherein the first contact and the second contact each have a metal outer layer away from the absorbing medium and a doped inner layer towards the absorbing medium.

9. The device of claim 8, wherein the inner layer of the first contact and the second contact is the same material as the first membrane layer and the second membrane layer.

10. The device of claim 1, wherein the first contact extracts electron holes and the second contract extracts electrons.

11. A method for providing a carrier selective contact device comprising:
providing an absorbing medium for absorbing light having a first side and a second side;
providing a first membrane layer having a first side and a second side, wherein the first side of the first membrane layer is in contact with the first side of the absorbing medium;
providing a second membrane layer having a first side and a second side, wherein the first side of the second membrane layer is in contact with the second side of the absorbing medium;
providing a first contact in contact with the second side of the first membrane layer; and
providing a second contact in contact with the second side of the second membrane layer,
wherein a first band alignment mismatch between the first contact and the absorbing medium causes a first surface of the absorbing medium on the first side of the absorbing medium to be in inversion, and
wherein a second band alignment mismatch between the second contact and the absorbing medium causes a second surface of the absorbing medium on the second side of the absorbing medium to be under accumulation.

12. The method of claim 11, wherein the first surface of the absorbing medium has an inversion region that provides an electric field that selectively extracts a first carrier of a particular polarity while repelling a second carrier of the opposite polarity of the first carrier.

13. The method of claim 12, wherein the second surface of the absorbing medium has an accumulation region that provides an electric field that selectively extracts the second carrier while repelling the first carrier.

14. The method of claim 11, wherein the absorbing medium is c-Si.

15. The method of claim 11, wherein the first membrane layer is Gallium Phosphide.

16. The method of claim 11, wherein the second membrane layer is one of a-Si and a-SiC.

17. The method of claim 11, wherein the absorbing medium is 50-80 μm.

18. The method of claim 11, wherein the first contact and the second contact each have a metal outer layer away from the absorbing medium and a doped inner layer towards the absorbing medium.

19. The method of claim 18, wherein the inner layer of the first contact and the second contact is the same material as the first membrane layer and the second membrane layer.

20. The method of claim 11, wherein the first contact extracts electron holes and the second contract extracts electrons.
